(19) United States
(12) Patent Application Publication
(10) Pub. No.: US 2026/0025997 A1
(43) Pub. Date: Jan. 22, 2026

(54) MEMORY CHANNEL STRUCTURE

(71) Applicant: Micron Technology, Inc., Boise, ID (US)

(72) Inventors: Marc AOULAICHE, Boise, ID (US); Donghwa LEE, Boise, ID (US); Srinath VENKATESAN, Boise, ID (US)

(21) Appl. No.: 19/214,831

(22) Filed: May 21, 2025

Related U.S. Application Data
(60) Provisional application No. 63/672,153, filed on Jul. 16, 2024.

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

Embodiments described herein relate to various structures, integrated assemblies, and memory devices. In some embodiments, a semiconductor device includes a layer stack including dielectric layers alternating with conductive layers and a pillar structure penetrating into the layer stack. The pillar structure includes a semiconductive layer, a dielectric fill; and a dielectric layer that is between the semiconductive layer and the dielectric fill and that includes a crystalline structure. The semiconductor devices includes a plug structure penetrating into the pillar structure, where the plug structure has a first portion on the semiconductive layer and has a second portion on the dielectric layer.

### CROSS-REFERENCE TO RELATED APPLICATION

This Patent Application claims priority to U.S. Provisional Patent Application No. 63/672, 153, filed on Jul. 16, 2024, entitled “MEMORY CHANNEL STRUCTURE,” and assigned to the assignee hereof. The disclosure of the prior Application is considered part of and is incorporated by reference into this Patent Application.

### TECHNICAL FIELD

The present disclosure generally relates to semiconductor devices and methods of forming semiconductor devices. For example, the present disclosure relates to a memory channel structure with a hardened liner.

### BACKGROUND

Memory devices provide data storage for electronic systems. Flash memory is a type of non-volatile memory, meaning that the memory retains data in the absence of a power supply. As an example, an electronic device may use flash memory in a solid state drive (SSD) for non-volatile storage of information, rather than a hard disk drive that uses magnetic disks for storage. NAND is a type of flash memory that has advantages over hard disk drives, such as lower erase times, lower write times, and less chip area per memory cell, which allows for more storage density and lower cost. The memory cells in NAND memory may be configured or formed in vertical stacks. This arrangement is sometimes called vertical NAND or three-dimensional (3D) NAND. 3D NAND arrangements enable a greater quantity of memory cells per chip surface area because of the vertical stacking of memory cells. 3D NAND arrangements also enable more options for the placement of cells to avoid interference and electron leakage, which can improve memory device performance. As the demand for storage capacity and performance increases, improvements in NAND architecture and improved methods for fabricating NAND memory are desirable.

### BRIEF DESCRIPTION OF THE DRAWINGS

FIG. 1 is a diagram illustrating an example of components included in a memory device described herein.

FIG. 2 is a diagram illustrating an example of a NAND memory array described herein.

FIG. 3 is a diagram illustrating an example of a 3D NAND memory array described herein.

FIGS. 4A-4C include diagrammatic views related to an example memory device structure described herein.

FIG. 5 is a flowchart of an example method of forming an integrated assembly or memory device having a pillar structure with a hardened liner described herein.

FIGS. 6A-6H are diagrammatic views showing formation of a pillar structure having a hardened liner at example process stages of an example process.

### DETAILED DESCRIPTION

A semiconductor device may include a memory structure, such as a three-dimensional (3D) NAND memory block. The 3D NAND memory block often includes a string of memory cells that are vertically arranged.

To form the string of memory cells, which may correspond to select gate cells, a pillar structure may penetrate through a stack of conductive layers alternating with dielectric layers. A region in which a conductive layer (e.g., a word line) intersects with an outer layer of the pillar structure (e.g., a channel layer) may constitute a gate (e.g., a select gate) of a select gate cell of the string of memory cells. The channel layer of the pillar structure may be polysilicon and include a particular concentration of impurities (e.g., a particular concentration of a boron dopant) such that a threshold voltage (Vt) of the pillar structure (e.g., a threshold voltage of a channel for a select gate cell) satisfies a functional performance threshold.

The memory structure may further include a plug structure (e.g., a digit line) that penetrates into the pillar structure. The plug structure may be polysilicon and include a particular concentration of impurities (e.g., a particular concentration of a phosphorous dopant) such that the plug structure satisfies a conductivity performance threshold.

Techniques to form the pillar structure may include forming a liner layer over or on the channel layer and forming a dielectric fill over or on the liner layer. During a recessing operation that removes a portion of the dielectric fill to form a cavity for the plug structure, portions of the liner layer may be damaged or removed to expose a portion of the channel layer.

After formation of the pillar structure and the plug structure (e.g., which combine to form a de-integrated select gate drain (dGSD) structure), operations to form additional features of the memory structure, such as a lateral contact or a select gate source structure, have a high thermal budget. The high thermal budget operations (e.g., high temperature operations) may cause a threshold voltage of the select gate cells to shift due to impurities diffusing from the plug structure into the channel layer. The shifting of the threshold voltage may cause the dGSD structure to no longer satisfy a functional performance threshold, thereby reducing an operating range of the memory structure.

Some embodiments described herein include a memory structure including a dGSD structure with a hardened liner layer. Techniques to form the dGSD structure, which may include a select gate cell of a 3D NAND memory block, include depositing a liner layer over a channel layer and annealing the liner layer to form the hardened liner layer. After formation of the hardened liner layer, a dielectric fill is formed adjacent to the hardened liner layer. During a recessing operation that forms cavities in the dielectric fill to accommodate a plug structure, portions of the hardened liner layer over the channel layer are preserved. The preserved portions of the hardened liner layer over the channel layer may reduce a likelihood of impurities diffusing from the plug structure into the channel layer during subsequent, high temperature operations used to form other features of the memory structure.

In this way, a threshold voltage of the dGSD structure is maintained or increased to satisfy a functional performance threshold. By satisfying the functional performance threshold, an operating range of the memory structure may be expanded to increase a quality or a reliability of a semiconductor device including the memory structure.

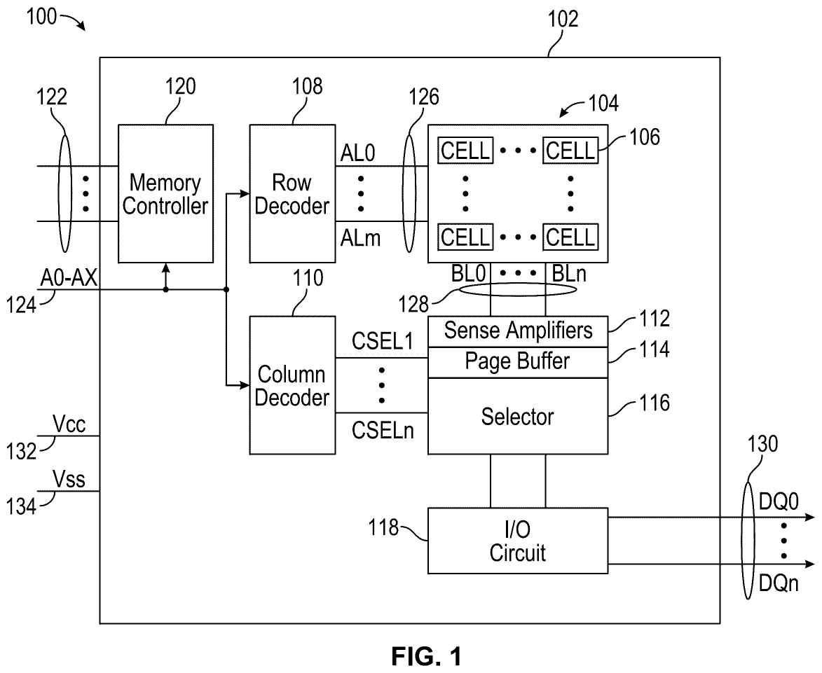

FIG. 1 is a diagram illustrating an example 100 of components included in a memory device 102 described herein. The memory device 102 may include a memory array 104 having multiple memory cells 106 (e.g., select gate cells). The memory device 102 may include one or more components (e.g., circuits) to transmit signals to or perform memory operations on the memory array 104. For example, the memory device 102 may include a row decoder 108, a column decoder 110, one or more sense amplifiers 112, a page buffer 114, a selector 116, an input/output (I/O) circuit 118, and a memory controller 120.

The memory controller 120 may control memory operations of the memory device 102 according to one or more signals received via one or more control lines 122, such as one or more clock signals or control signals that indicate an operation (e.g., write, read, or erase) to be performed. The memory controller 120 may determine one or memory cells 106 upon which the operation is to be performed based on one or more signals received via one or more address lines 124, such as one or more address signals (shown as A0-AX). A host device external from the memory device 102 may control the values of the control signals on the control lines 122 or the address signals on the address line 124.

The memory device 102 may use access lines 126 (sometimes called word lines or row lines, and shown as AL0-ALm) and bit lines 128 (sometimes called digit lines, data lines, or column lines, and shown as BL0-BLn) to transfer data to or from one or more of the memory cells 106. For example, the row decoder 108 and the column decoder 110 may receive and decode the address signals (A0-AX) from the address line 124 and may determine which of the memory cells 106 are to be accessed based on the address signals. The row decoder 108 and the column decoder 110 may provide signals to those memory cells 106 via one or more access lines 126 and one or more bit lines 128, respectively.

For example, the column decoder 110 may receive and decode address signals into one or more column select signals (shown as CSEL1-CSELn). The selector 116 may receive the column select signals and may select data in the page buffer 114 that represents values of data to be read from or to be programmed into memory cells 106. The page buffer 114 may be configured to store data received from a host device before the data is programmed into relevant portions of the memory array 104, or the page buffer 114 may store data read from the memory array 104 before the data is transmitted to the host device. The sense amplifiers 112 may be configured to determine the values to be read from or written to the memory cells 106 using the bit lines 128. For example, in a selected string of memory cells 106, a sense amplifier 112 may read a logic level in a memory cell 106 in response to a read current flowing through the selected string to a bit line 128. The I/O circuit 118 may transfer values of data into or out of the memory device 102 (e.g., to or from a host device), such as into or out of the page buffer 114 or the memory array 104, using I/O lines 130 (shown as (DQ0-DQn)).

The memory controller 120 may generate or receive positive and negative supply signals, such as a supply voltage (Vcc) 132 and a negative supply (Vss) 134 (e.g., a ground potential), from an external source or power supply (e.g., an internal battery, an external battery, or an AC-to-DC converter).

As indicated above, FIG. 1 is provided as an example. Other examples may differ from what is described with regard to FIG. 1.

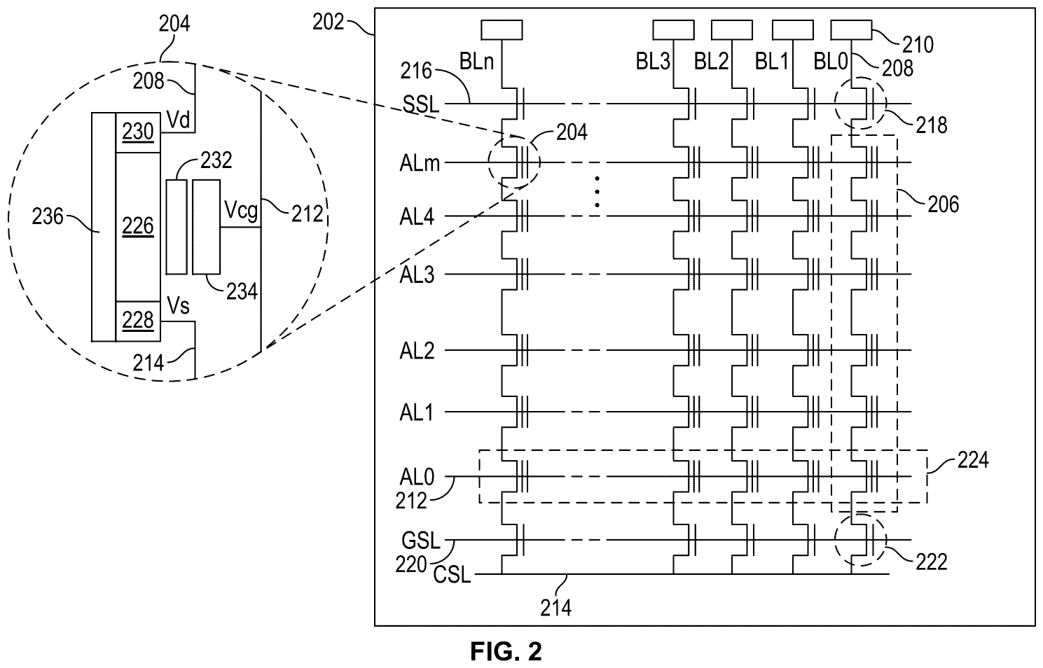

FIG. 2 is a diagram illustrating an example 200 of a NAND memory array 202 described herein. The NAND memory array 202 may correspond to the memory array 104 described above in connection with FIG. 1. The memory array 202 may be part of a three-dimensional stack of memory arrays, such as 3D NAND flash memory.

The memory array 202 includes multiple memory cells 204 (e.g., select gate cells). A memory cell 204 may store an analog value, such as an electrical voltage or an electrical charge, that represents a data state (e.g., a digital value). The analog value and corresponding data state depend on a quantity of electrons trapped or present within a region of the memory cell 204 (e.g., in a charge trap, such as a floating gate), as described below.

A NAND string 206 (sometimes called a string) may include multiple memory cells 204 connected in series. A NAND string 206 is coupled to a bit line 208 (sometimes called a digit line or a column line, and shown as BL0-BLn). Data can be read from or written to the memory cells 204 of a NAND string 206 via a corresponding bit line 208 using one or more input/output (I/O) components 210 (e.g., an I/O circuit, an I/O bus, a page buffer, or a sensing component, such as a sense amplifier). Memory cells 204 of different NAND strings 206 (e.g., one memory cell 204 per NAND string 206) may be coupled with one another via access lines 212 (sometimes called word lines or row lines, and shown as AL0-ALm) that select which row (or rows) of memory cells 204 is affected by a memory operation (e.g., a read operation or a write operation).

A NAND string 206 may be connected to a bit line 208 at one end and a common source line (CSL) 214 at the other end. A string select line (SSL) 216 may be used to control respective string select transistors 218. A string select transistor 218 selectively couples a NAND string 206 to a corresponding bit line 208. A ground select line (GSL) 220 may be used to control respective ground select transistors 222. A ground select transistor 222 selectively couples a NAND string 206 to the common source line 214.

A “page” of memory (or “a memory page”) may refer to a group of memory cells 204 connected to the same access line 212, as shown by reference number 224. In some embodiments (e.g., for single-level cells), the memory cells 204 connected to an access line 212 may be associated with a single page of memory. In some embodiments (e.g., for multi-level cells), the memory cells 204 connected to an access line 212 may be associated with multiple pages of memory, where each page represents one bit stored in each of the memory cells 204 (e.g., a lower page that represents a first bit stored in each memory cell 204 and an upper page that represents a second bit stored in each memory cell 204). In NAND memory, a page is the smallest physically addressable data unit for a write operation (sometimes called a program operation).

In some embodiments, a memory cell 204 is a floating-gate transistor memory cell. In this case, the memory cell 204 may include a channel 226, a source region 228, a drain region 230, a floating gate 232, and a control gate 234. The source region 228, the drain region 230, and the channel 226 may be on a substrate 236 (e.g., a semiconductor substrate). A memory device may store a data state in the memory cell 204 by charging the floating gate 232 to a particular voltage associated with the data state or to a voltage that is within a range of voltages associated with the data state. This results in a predefined amount of current flowing through the channel 226 (e.g., from the source region 228 to the drain region 230) when a specified read voltage is applied to the control gate 234 (e.g., by a corresponding access line 212 connected to the control gate 234). Although not shown, a tunnel oxide layer (or tunnel dielectric layer) may be interposed between the floating gate 232 and the channel 226, and a gate oxide layer (e.g., a gate dielectric layer) may be interposed between the floating gate 232 and the control gate 234. As shown, a drain voltage Vd may be supplied from a bit line 208, a control gate voltage Veg may be supplied from an access line 212, and a source voltage Vs may be supplied via the common source line 214 (which, in some embodiments, is a ground voltage).

To write or program the memory cell 204, Fowler-Nordheim tunneling may be used. For example, a strong positive voltage potential may be created between the control gate 234 and the channel 226 (e.g., by applying a large positive voltage to the control gate 234 via a corresponding access line 212) while current is flowing through the channel 226 (e.g., from the common source line 214 to the bit line 208, or vice versa). The strong positive voltage at the control gate 234 causes electrons within the channel 226 to tunnel through the tunnel oxide layer and be trapped in the floating gate 232. These negatively charged electrons then act as an electron barrier between the control gate 234 and the channel 226 that increases the threshold voltage of the memory cell 204. The threshold voltage is a voltage required at the control gate 234 to cause current (e.g., a threshold amount of current) to flow through the channel 226. Fowler-Nordheim tunneling is an example technique for storing a charge in the floating gate, and other techniques, such as channel hot electron injection, may be used.

To read the memory cell 204, a read voltage may be applied to the control gate 234 (e.g., via a corresponding access line 212), and an I/O component 210 (e.g., a sense amplifier) may determine the data state of the memory cell 204 based on whether current passes through the memory cell 204 (e.g., the channel 226) due to the applied voltage. A pass voltage may be applied to all memory cells 204 (other than the memory cell 204 being read) in the same NAND string 206 as the memory cell 204 being read. For example, the pass voltage may be applied on each access line 212 other than the access line 212 of the memory cell 204 being read (e.g., where the read voltage is applied). The pass voltage is higher than the highest read voltage associated with any memory cell data states so that all of the other memory cells 204 in the NAND string 206 conduct, and the I/O component 210 can detect a data state of the memory cell 204 being read by sensing current (or lack thereof) on a corresponding bit line 208. For example, in a single-level memory cell that stores one of two data states, the data state is a “1” if current is detected, and the data state is a “0” if current is not detected. In a multi-level memory cell that stores one of three or more data states, multiple read voltages are applied, over time, to the control gate 234 to distinguish between the three or more data states and determine a data state of the memory cell 204.

To erase the memory cell 204, a strong negative voltage potential may be created between the control gate 234 and the channel 226 (e.g., by applying a large negative voltage to the control gate 234 via a corresponding access line 212). The strong negative voltage at the control gate 234 causes trapped electrons in the floating gate 232 to tunnel back across the oxide layer from the floating gate 232 to the channel 226 and to flow between the common source line 214 and the bit line 208. This removes the electron barrier between the control gate 234 and the channel 226 and decreases the threshold voltage of the memory cell 204 (e.g., to an empty or erased state, which may represent a “1”). In NAND memory, a block is the smallest unit of memory that can be erased. A block of NAND memory includes multiple pages. Thus, an individual page of a block cannot be erased without erasing every other page of the block. In some embodiments, a block may be divided into multiple sub-blocks. A sub-block is a portion of a block and may include a subset of pages of the block or a subset of memory cells of the block.

As indicated above, FIG. 2 is provided as an example. Other examples may differ from what is described with regard to FIG. 2.

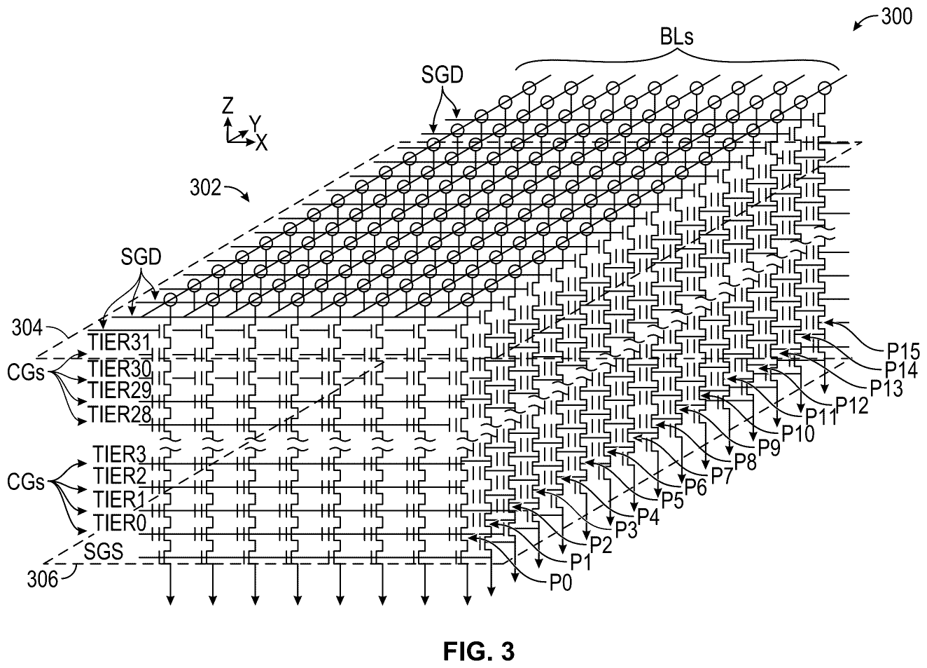

FIG. 3 is a diagram illustrating an example 300 of a 3D NAND memory array 302 described herein. The 3D NAND memory array 302 may correspond to the memory array 104 described above in connection with FIG. 1 or the NAND memory array 202 described above in connection with FIG. 2.

The 3D NAND memory array 302 includes multiple strings of memory cells. A string includes multiple tiers of charge storage transistors stacked in a first direction, shown as the Z direction. The charge storage transistors are stacked source to drain from a source-side select gate (SGS) to a drain-side select gate (SGD). In the example 300 of FIG. 3, each string includes 32 tiers (shown as TIER0 through TIER31). In other examples, each string of memory cells may include a different quantity of tiers (e.g., 8 tiers, 16 tiers, 64 tiers, or 128 tiers). The memory cells of a particular string may share a common channel region, such as one formed in a respective pillar of semiconductor material (e.g., polysilicon) about which the string of memory cells is formed.

Along a second direction, shown as the Y direction, multiple strings of memory cells are connected along bit lines (BLs). For example, a first group of strings is coupled to a first bit line extending in the second direction, a second group of strings is coupled to a second bit line extending in the second direction, and so on.

Along a third direction, shown as the X direction, memory cells in the same tier but in different strings are arranged in memory pages (shown as P0 through P15). For example, a group of memory cells in a tier may be coupled to the same access line to form a page (or multiple pages, in the example of multi-level cells). Within a page, each tier represents a row of memory cells, and each string of memory cells represents a column. A block of memory cells can include multiple pages, such as 128 pages or 384 pages.

Each memory cell includes a control gate (CG) coupled to an access line, as described above in connection with FIG. 2. The access line collectively couples the control gates of memory cells in a specific tier or a portion of a tier. A tier in the 3D NAND memory array 302, can be accessed or controlled using an access line. For example, the 3D NAND memory array 302 may include a first level of semiconductor material 304 (e.g., polysilicon) that couples the control gates of each memory cell in TIER31. Similar respective levels of metal or semiconductor material may couple the control gates for each respective tier. As further shown, the 3D NAND memory array 302 may include a second level of semiconductor material 306 that couples the source-side select gates (SGS) of the array. Specific strings of memory cells in the 3D NAND memory array 302 can be accessed, selected, or controlled using a combination of bit lines and select gates, and specific memory cells at one or more tiers in the specific strings can be accessed, selected, or controlled using one or more access lines.

As indicated above, FIG. 3 is provided as an example. Other examples may differ from what is described with regard to FIG. 3. For example, the number of memory cells, strings, tiers, bit lines, access lines, or pages may be greater than or less than those shown in FIG. 3.

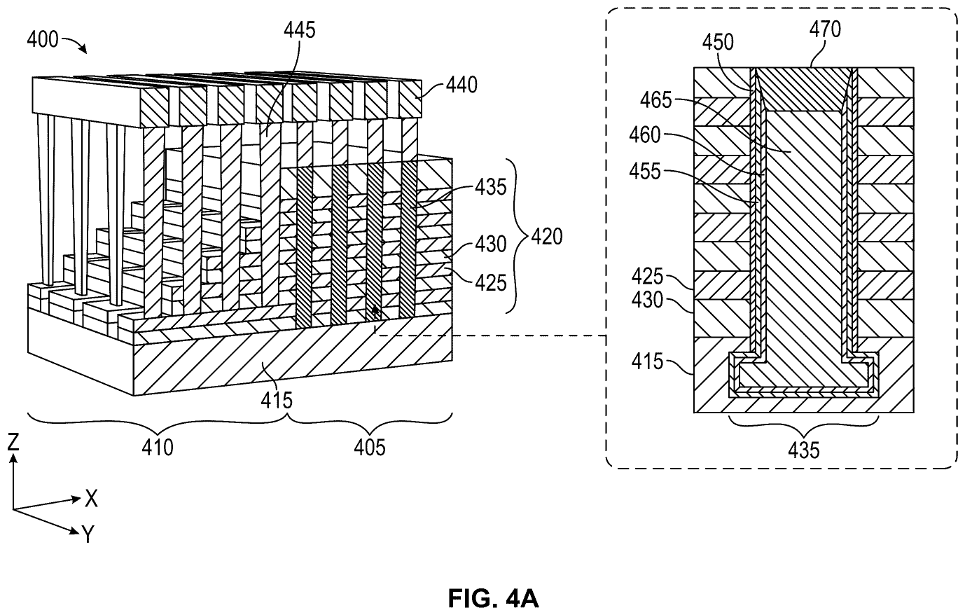

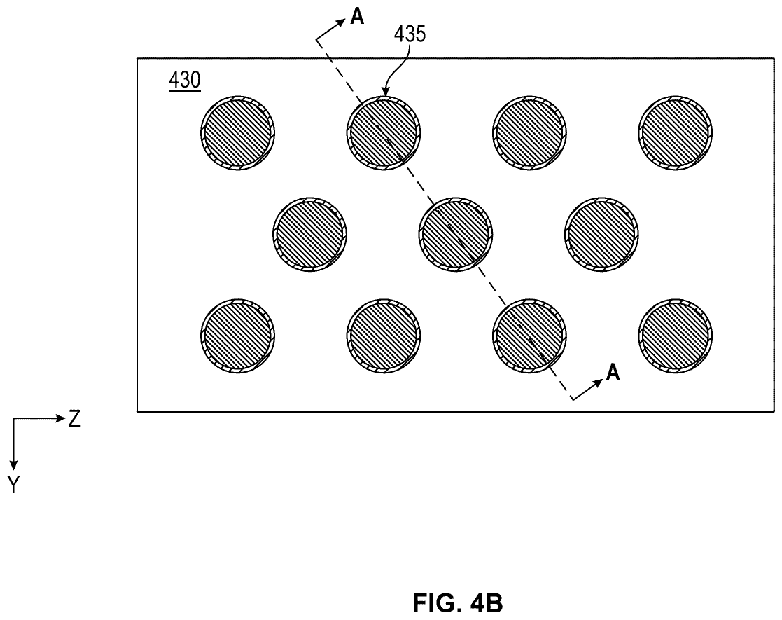

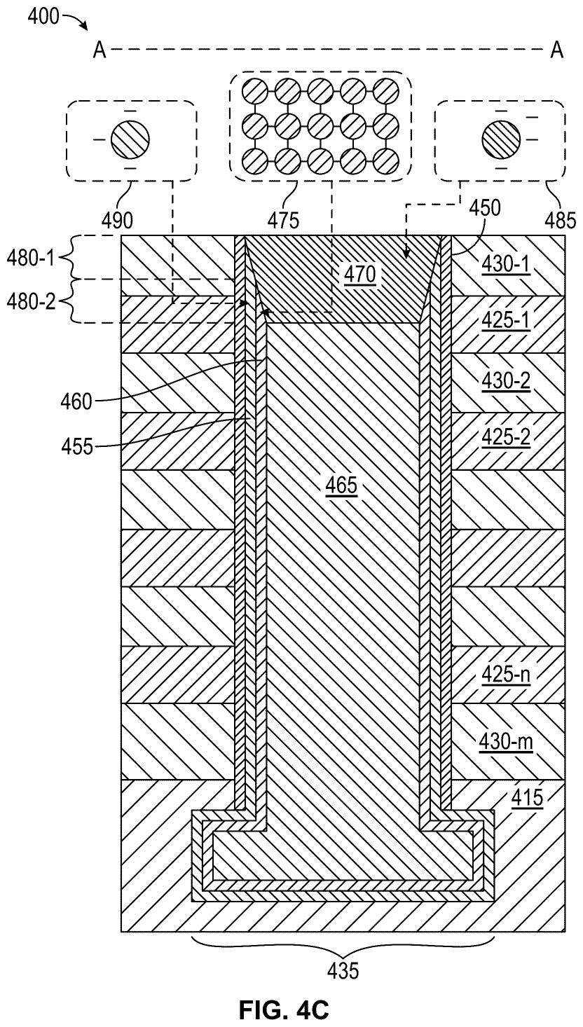

FIGS. 4A-4C include diagrammatic views related to an example memory device structure 400 described herein. In some embodiments, the memory device structure 400 corresponds to a structure of a three-dimensional (3D) NAND memory device.

As shown in the isometric view on the left side of FIG. 4A, the memory device structure 400 includes a memory block region 405 and a staircase region 410. The memory block region 405 and the staircase region 410 each include portions of a substrate 415 and a tiered structure 420.

The substrate 415 may comprise, consist of, or consist essentially of semiconductive material. The semiconductive material may comprise, consist of, or consist essentially of silicon (e.g., polysilicon or polycrystalline silicon). Alternatively, and in some embodiments, the substrate 415 comprises, consists of, or consists essentially of silicon carbide, gallium nitride, or a type III-V element, among other examples.

The tiered structure 420 may include conductive layers 425 that are interspersed (e.g., alternate vertically) with dielectric layers 430. Each of the conductive layers 425 may be an electrical conductor and may comprise, consist of, or consist essentially of conductive material. As used herein, a conductive material may comprise, consist of, or consist essentially of a metal (e.g., titanium, tungsten, cobalt, nickel, platinum, or ruthenium), a metal composition (e.g., a metal silicide, a metal carbide, or a metal nitride, such as titanium nitride or titanium silicon nitride), or a conductively-doped semiconductor material (e.g., conductively-doped silicon, conductively-doped germanium, or conductively-doped gallium arsenide), among other examples. Furthermore, one or more of the conductive layers 425 may correspond to a word line layer of the memory device structure 400.

Each of the dielectric layers 430 may be an electrical insulator and may comprise, consist of, or consist essentially of insulative material. As used herein, an insulative material may comprise, consist of, or consist essentially of an oxide (e.g., silicon oxide, aluminum oxide, or another suitable oxide material) or a nitride (e.g., silicon nitride aluminum nitride, or another suitable nitride material), among other examples. Furthermore, the dielectric layers 430 may correspond to an inter-gate dielectric layer of the memory device structure 400.

Within the memory block region 405, one or more pillar structures 435 may penetrate through the tiered structure 420. The pillar structures 435 may each include an annular distribution (e.g., one or more layered rings) of semiconductive materials or insulative materials that form a channel or a storage cell of the memory device structure 400.

The memory device structure 400 may further include one or more conductive structures 440 that are above the tiered structure 420 and that span the memory block region 405 or the staircase region 410. The conductive structures 440 may each include one or more conductive materials. Furthermore, each of the conductive structures 440 may form a digit line of the memory device structure 400 (e.g., a digit line).

The memory device structure 400 may further include one or more contact structures 445 that are vertically-oriented and connect the conductive structures 440 with the pillar structures 435 or conductive layers 425. The contact structures 445 may each include one or more conductive materials as described above.

As shown in the detailed side section view in the right side of FIG. 4A, each of the pillar structures 435 includes a gate dielectric layer 450, a channel layer 455, a hardened liner 460, and a dielectric layer 465. The gate dielectric layer 450 may be an electrical insulator and may comprise, consist of, or consist essentially of insulative material. The insulative material may comprise, consist of, or consist essentially of silicon dioxide or silicon nitride, among other examples.

The channel layer 455 (e.g., a semiconductive layer) may comprise, consist of, or consist essentially a semiconductive material doped with impurities that enable the channel layer 455 to be a conductive layer under an applied voltage (e.g., under an applied threshold voltage, or Vₜ). The semiconductive material may comprise, consist of, or consist essentially of silicon (e.g., polycrystalline silicon or polysilicon). Alternatively, and in some embodiments, the channel layer 455 consists of, or consists essentially of polycrystalline silicon, silicon carbide, gallium nitride, a type III-V element, or another suitable semiconductive material, among other examples. In some embodiments, the impurities include a p-type dopant such as boron or another suitable p-type dopant, among other examples.

The hardened liner 460 may comprise, consist, or consist essentially of insulative material. As used herein, an insulative material may comprise, consist of, or consist essentially of an oxide (e.g., silicon oxide, aluminum oxide, or another suitable oxide material), a nitride (e.g., silicon nitride aluminum nitride, or another suitable nitride material), among other examples.

Further, and as described in greater detail in connection with FIG. 3, FIG. 4A through FIG. 6H, and elsewhere herein, the insulative material may be deposited as an amorphous material (e.g., a material that lacks a well-defined, regular crystalline structure) and subsequently annealed to include an ordered crystalline structure and form the hardened liner 460. As an example, and in some embodiments, the hardened liner 460 may include an annealed dielectric material (e.g., an annealed oxide) that has the ordered crystalline structure.

The dielectric layer 465 (e.g., a dielectric fill) may comprise, consist, or consist essentially of insulative material. As used herein, an insulative material may comprise, consist of, or consist essentially of an oxide (e.g., silicon oxide, aluminum oxide, or another suitable oxide material) or a nitride (e.g., silicon nitride aluminum nitride, or another suitable nitride material), among other examples.

In some embodiments, and as shown in FIG. 4A, a plug structure 470 (e.g., a bit line contact structure) penetrates into the pillar structure 435. The plug structure 470 may comprise, consist of, or consist essentially of a semiconductive material doped with impurities that enable the plug structure 470 to be electrically conductive. The semiconductive material may comprise, consist of, or consist essentially of silicon (e.g., polycrystalline silicon or polysilicon), among other examples. Alternatively, and in some embodiments, the plug structure 470 may comprise, consist of, or consist essentially of silicon carbide, gallium nitride, a type III-V element, or another suitable semiconductive material, among other examples. Furthermore, and in some embodiments, the impurities include an n-type dopant such as phosphorous or another suitable n-type dopant, among other examples.

In some embodiments, the plug structure 470 electrically couples with one of the conductive structures 440 (e.g., a digit line) of the memory device structure 400. Additionally, or alternatively and in some embodiments, the plug structure 470 is included as part of one of the conductive structures 440.

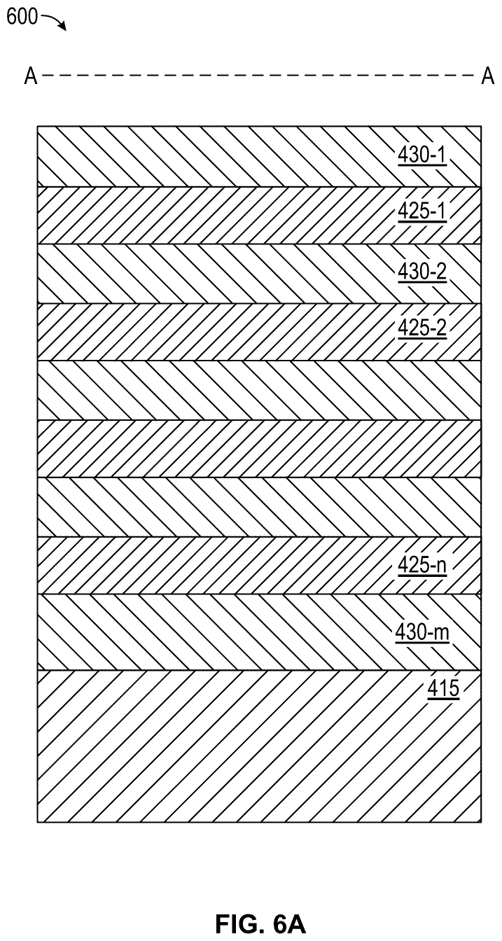

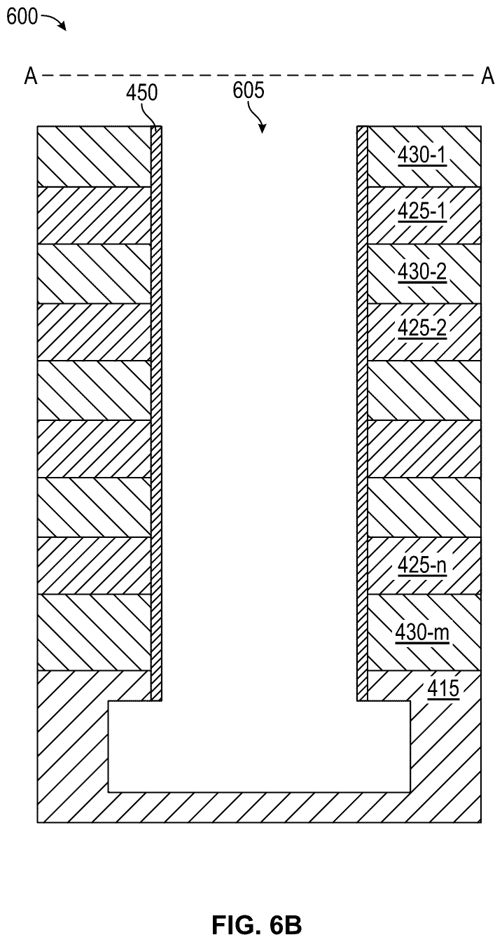

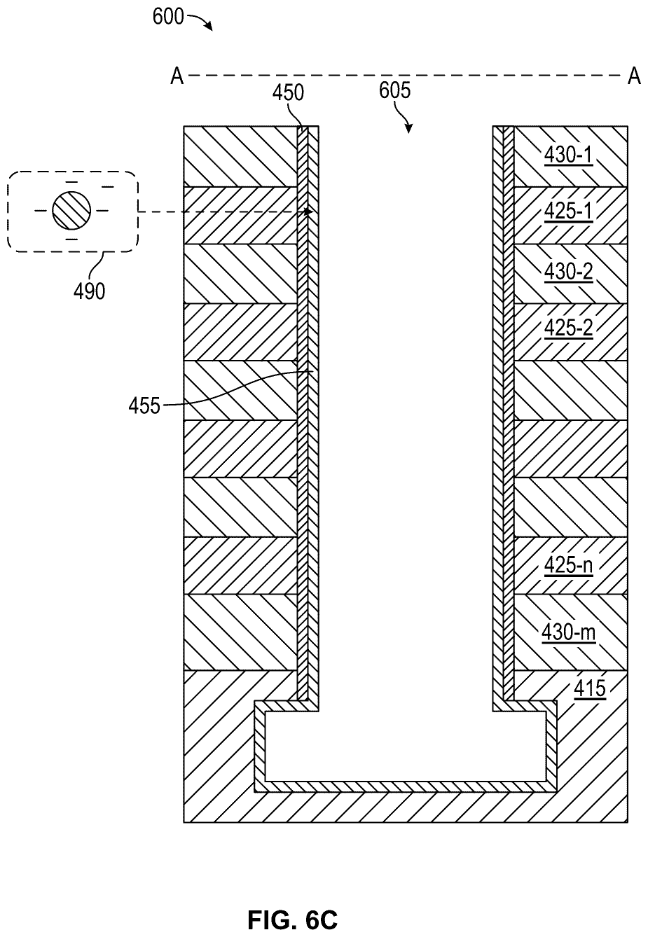

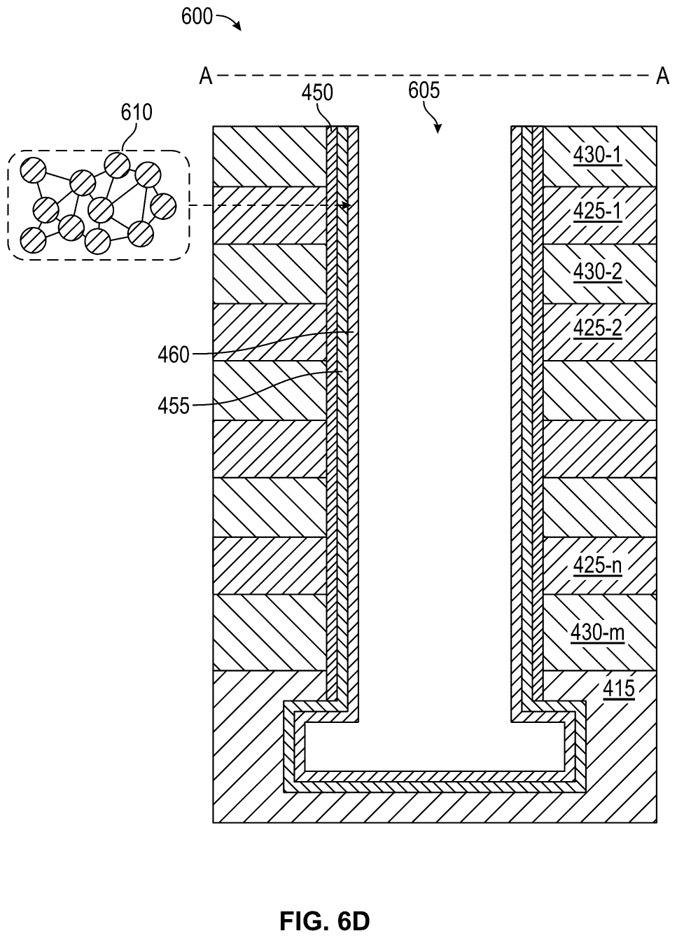

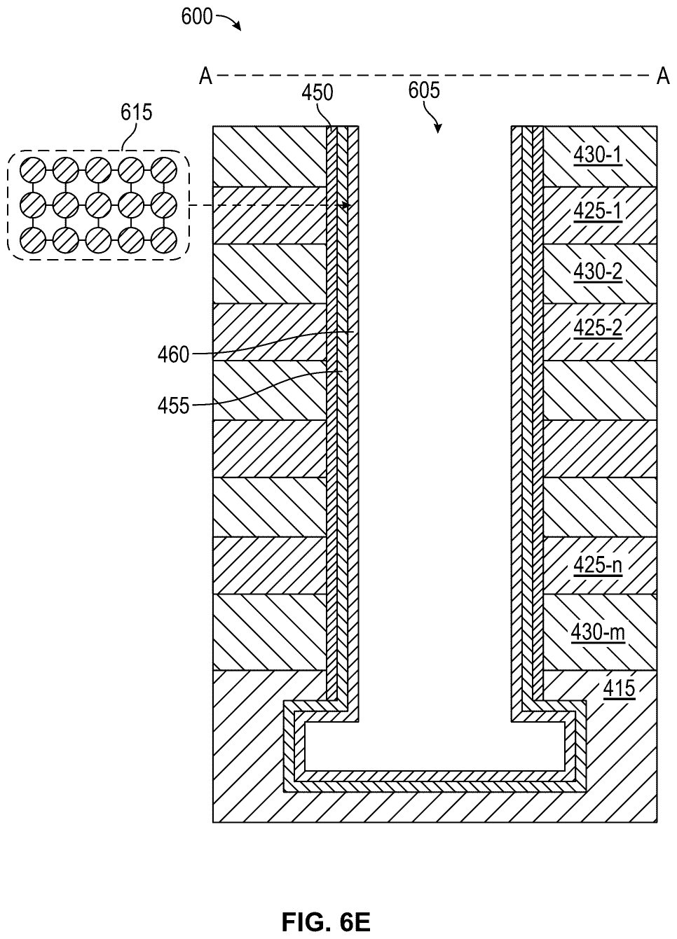

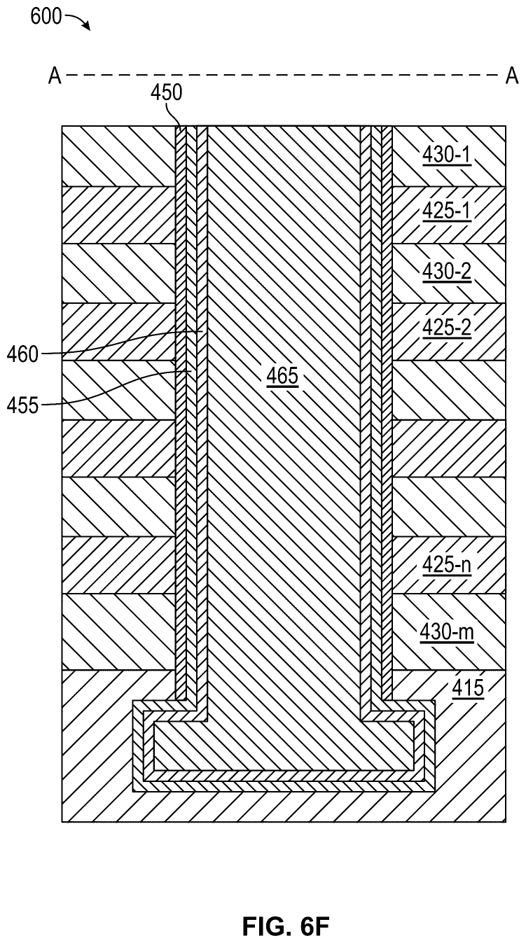

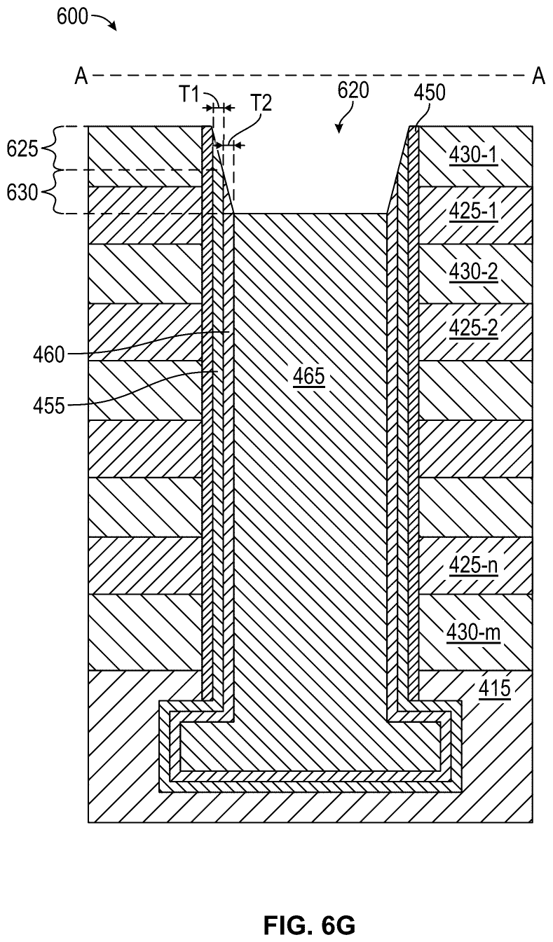

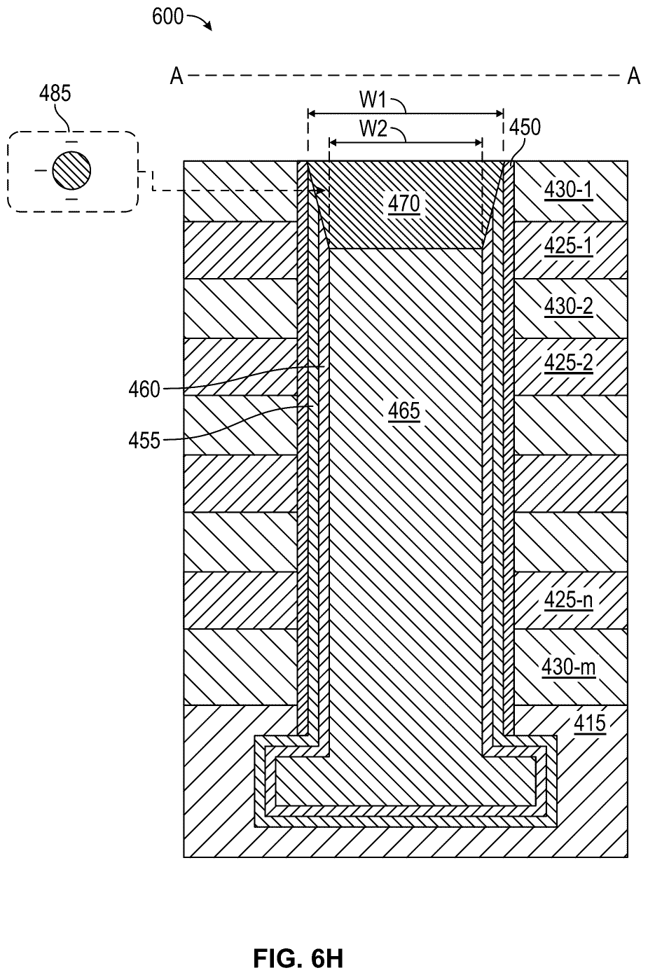

FIG. 4B shows an example top view of the pillar structures 435 in relation to the dielectric layer 430. A section line A-A is drawn through the pillar structures and may be used as a reference with respect to FIGS. 4C and 6A-6H.

FIG. 4C shows additional details of the memory device structure 400 including the pillar structure 435. As shown in FIG. 4C, the hardened liner 460 may include a crystalline structure 475. For example, the crystalline structure 475 may be an ordered structure such as a single crystal lattice structure, in which a uniform and continuous arrangement of atoms, ions, or molecules extends in three dimensions to exhibit a long-range order and a well-defined repeating pattern throughout the hardened liner 460. Such a single crystal lattice structure may be a quartz lattice structure. Alternatively, the crystalline structure 475 may be an ordered structure such as a polycrystalline lattice structure, in which multiple crystalline regions (grains) each have an orientation and atomic arrangement, causing the hardened liner 460 to have a mosaic-like structure. Alternatively, the crystalline structure 475 may be an ordered structure such as a superlattice structure, in which a periodic arrangement of two or more distinct crystalline layers forms a composite material within the hardened liner layer that has properties derived from the interaction between the crystalline layers. In some embodiments, and in contrast to having the crystalline structure 475, the hardened liner 460 may include another structure such as a spinel structure, among other examples. As described in greater detail in connection with FIGS. 6A-6H and elsewhere herein, the hardened liner 460 (e.g., the crystalline structure 475) may be resistant to an etchant and cause portions of the hardened liner 460 to be retained during recessing of the dielectric layer 465 that forms a cavity for the plug structure 470.

As further shown in FIG. 4C, a portion 480-1 (e.g., a first, upper portion) of the plug structure 470 is directly on the channel layer 455. In some embodiments, and as shown in FIG. 4C, the portion 480-1 overlaps at least a portion of the dielectric layer 430-1. Additionally, or alternatively, the dielectric layer 430-1 (e.g., an inter-gate dielectric layer) may be adjacent to the portion 480-1 and the conductive layer 425-1 may be laterally adjacent to the portion 480-2.

Additionally, or alternatively, a portion 480-2 (e.g., a second, lower portion) of the plug structure 470 is directly on the hardened liner 460, where the hardened liner 460 separates the portion 480-2 from the channel layer 455. In some embodiments, and as shown in FIG. 4C, the portion 480-2 overlaps at least a portion of the conductive layer 425-1.

As further shown in FIG. 4C, the plug structure 470 may include a dopant 485 (e.g., impurities) implanted into the plug structure 470. In some embodiments, the dopant 485 is an n-type dopant (e.g., phosphorous) that introduces extra electrons into a lattice of the plug structure 470, creating a surplus of negative charge carriers to enhance electron dominated conductivity characteristics of the plug structure 470.

Additionally, or alternatively, the channel layer 455 may include a dopant 490 implanted into the channel layer 455. In some embodiments, the dopant 490 is a p-type dopant (e.g., boron) that introduces “holes” of vacancies into a lattice of the channel layer, creating a surplus of positive charge carriers to enhance electron hole dominated conductivity characteristics of the channel layer 455. In other words, and in some embodiments, the channel layer 455 has an opposite type of dopant (e.g., a p-type dopant) as the plug structure 470 (e.g., an n-type dopant).

In some embodiments, the pillar structure 435 is exposed to a high temperature semiconductor manufacturing operation after formation. For example, the pillar structure 435 may be exposed to a chemical vapor deposition (CVD) operation or a physical vapor deposition (PVD) operation that forms a layer of a material above the pillar structure 435.

During the high temperature semiconductor manufacturing operation, a temperature of the plug structure 470, the hardened liner 460, or the channel layer 455 may be increased. At the increased temperature, a propensity for the dopant 490 to diffuse from the lower portion 480-2 of the plug structure 470 into the channel layer 455 (e.g., “down diffusion”) may increase. However, the presence of the channel layer 455 that includes the crystalline structure 475 and that is laterally adjacent to the lower portion 480-2 may inhibit an ability for the dopant 490 to diffuse from the plug structure 470 into the channel layer 455.

As indicated above, FIGS. 4A-4C are provided as an example. Other examples may differ from what is described with regard to FIGS. 4A-4C.

As described in connection with FIGS. 1-4C, and in some embodiments, a semiconductor device (e.g., the memory device structure 400) includes a layer stack including dielectric layers (e.g., the dielectric layers 430) alternating with conductive layers (e.g., the conductive layers 425). The semiconductor device includes a pillar structure (e.g., the pillar structure 435) penetrating into the layer stack. The pillar structure includes a semiconductive layer (e.g., the channel layer 455), a dielectric fill (e.g., the dielectric layer 465), and a dielectric layer (e.g., the hardened liner 460) that is between the semiconductive layer and the dielectric fill and that includes a crystalline structure. The semiconductor device includes a plug structure (e.g., the plug structure 470) penetrating into the pillar structure. The plug structure includes a first portion (e.g., the portion 480-1) on the semiconductive layer and a second portion (e.g., the portion 480-2) on the dielectric layer.

Additionally, or alternatively and in some embodiments, an apparatus (e.g., a NAND memory device or a system including the memory device structure 400) includes a channel layer (e.g., the channel layer 455), a liner layer on the channel layer (e.g., the hardened liner 460), a dielectric layer (e.g., the dielectric layer 465) on the liner layer, and a digit line contact structure (e.g., the plug structure 470) penetrating into the dielectric layer. The digit line contact structure includes an upper portion (e.g., the portion 480-1) on the channel layer and a lower portion (e.g., the portion 480-2) that is separated from the channel layer by the liner layer.

In this way, a threshold voltage is maintained or increased to satisfy a functional performance threshold. By satisfying the functional performance threshold, an operating range of the semiconductor device or the apparatus may be expanded to increase a quality or a reliability of a semiconductor device or the apparatus.

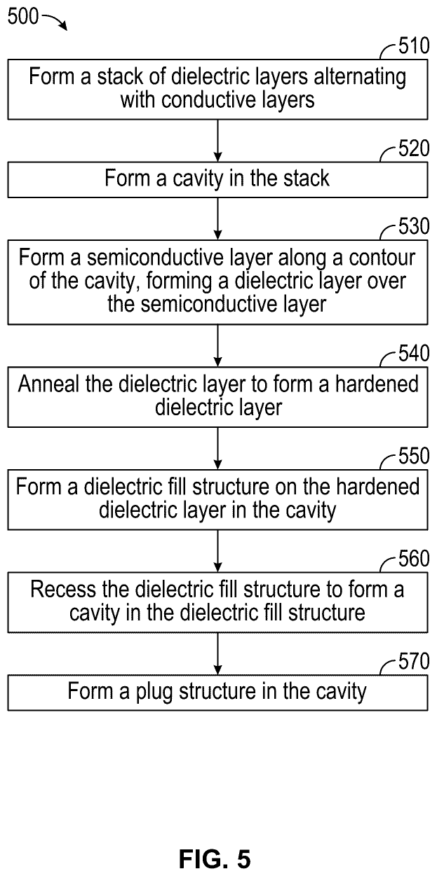

FIG. 5 is a flowchart of an example method 500 of forming an integrated assembly or memory device having a pillar structure (e.g., the pillar structure 435) with a hardened liner (e.g., the hardened liner 460) described herein. In some embodiments, and as described in greater detail in connection with FIGS. 6A-6H, one or more process blocks of FIG. 5 may be performed by various semiconductor manufacturing equipment.

As shown in FIG. 5, the method 500 may include forming a stack of dielectric layers (e.g., the dielectric layers 430) alternating with conductive layers (e.g., the conductive layers 425) (block 510). As further shown in FIG. 5, the method 500 may include forming a cavity in the stack (block 520). As further shown in FIG. 5, the method 500 may include forming a semiconductive layer (e.g., the channel layer 455) along a contour of the cavity and forming a dielectric layer over the semiconductive layer (block 530). As further shown in FIG. 5, the method 500 may include annealing the dielectric layer to form a hardened dielectric layer (e.g., the hardened liner 460) (block 540). As further shown in FIG. 5, the method 500 may include forming a dielectric fill (e.g., the dielectric layer 465) on the hardened dielectric layer in the cavity (block 550). As further shown in FIG. 5, the method 500 may include recessing the dielectric fill to form a cavity in the dielectric fill (block 560). As further shown in FIG. 5, the method 500 may include forming a plug structure (e.g., the plug structure 470) in the cavity (block 570).

The method 500 may include additional aspects, such as any single aspect or any combination of aspects described below or in connection with one or more other methods described elsewhere herein.

In a first aspect, forming the dielectric layer includes depositing a layer of a dielectric material having an amorphous structure.

In a second aspect, alone or in combination with the first aspect, annealing the dielectric layer to form the hardened dielectric layer includes transforming at least a portion of the dielectric material having the amorphous structure to include a crystalline structure (e.g., the crystalline structure 475).

In a third aspect, alone or in combination with one or more of the first and second aspects, annealing the dielectric layer includes using a rapid thermal processing operation.

In a fourth aspect, alone or in combination with one or more of the first through third aspects, recessing the dielectric fill includes using an etch operation to recess the dielectric fill, wherein the etch operation uses an etchant having a first etch rate for the dielectric fill, a second etch rate for the hardened dielectric layer, and a third etch rate for the semiconductive layer, wherein the first etch rate is greater than the second etch rate, and wherein the second etch rate is less than the third etch rate.

In a fifth aspect, alone or in combination with one or more of the first through fourth aspects, using the etch operation includes leaving a portion of the semiconductive layer along an upper sidewall of the cavity, and leaving a portion of the hardened dielectric layer along a lower sidewall of the cavity, wherein an average thickness of the portion of the hardened dielectric layer is greater than an average thickness of the portion of the semiconductive layer.

In a sixth aspect, alone or in combination with one or more of the first through fifth aspects, forming the plug structure in the cavity includes using an implant operation to form impurities (e.g., the dopant 485) in the plug structure.

In a seventh aspect, alone or in combination with one or more of the first through sixth aspects, the method 500 includes performing a semiconductor processing operation that increases a temperature of the plug structure, the hardened dielectric layer, and the semiconductive layer. In some embodiments, a portion of the hardened dielectric layer inhibits diffusion of the impurities into the semiconductive layer caused by the temperature to maintain and satisfy a voltage threshold of a channel that includes the semiconductive layer.

Although FIG. 5 shows example blocks of the method 500, in some embodiments, the method 500 may include additional blocks, fewer blocks, different blocks, or differently arranged blocks than those depicted in FIG. 5. In some embodiments, the method 500 may include forming the pillar structure 435, an integrated assembly that includes the pillar structure 435, any part described herein of the pillar structure 435, or any part described herein of an integrated assembly that includes the pillar structure 435. For example, the method 500 may include forming one or more of the parts of the memory device structure 400.

FIGS. 6A-6H are diagrammatic views showing formation of a pillar structure (e.g., the pillar structure 435) having a hardened liner (e.g., the hardened liner 460) at example process stages of an example process 600. In some embodiments, the process 600 described below in connection with FIGS. 6A-6H may correspond to the method 500 or one or more blocks of the method 500. However, the process described below is an example, and other example processes may be used to form the pillar structure, an integrated assembly that includes the pillar structure, or one or more parts of the pillar structure or the integrated assembly.

As shown in FIG. 4A, the process 600 may include forming (e.g., depositing or growing) a layer stack over or on the substrate 415. The layer stack may include the conductive layers 425 alternating with the dielectric layers 430.

The substrate 415 may comprise, consist of, or consist essentially of silicon (e.g., polycrystalline silicon) or another suitable semiconductive material, among other examples. The conductive layers 425 may comprise, consist of, or consist essentially of a metal (e.g., titanium, tungsten, cobalt, nickel, platinum, or ruthenium), a metal composition (e.g., a metal silicide, a metal carbine, or a metal nitride, such as titanium nitride or titanium silicon nitride), or a conductively-doped semiconductor material (e.g., conductively-doped silicon, conductively-doped germanium, or conductively-doped gallium arsenide), among other examples. The dielectric layers 430 may comprise, consist of, or consist essentially of silicon dioxide or another suitable dielectric material, among other examples.

As shown in FIG. 6B, the process 600 may include removing (e.g., etching) a portion of the layer stack to form a cavity 605. In some embodiments, one or more masks may be used to form the cavity 605. For example, one or more masks may be deposited or patterned on the dielectric layer 430-1 prior to removing material to form the cavity 605.

Further, and as shown in FIG. 6B, the process may include forming (e.g., depositing or growing) the gate dielectric layer 450 along sidewalls of the cavity 605. In some embodiments, forming the gate dielectric layer 450 includes forming a liner over the gate dielectric layer 450 and removing the liner using an exhuming operation that removes the liner and a temporary fill that occupies a portion of the cavity 605.

As shown in FIG. 6C, the process 600 may include forming (e.g., depositing or growing) the channel layer 455 over or along a contour of the cavity 605. In addition to including sidewalls of the cavity 605, the contour may include surfaces of the gate dielectric layer 450. The channel layer 455 may comprise, consist of, or consist essentially of silicon (e.g., polycrystalline silicon) or another suitable semiconductive material, among other examples. Additionally, the process 600 in FIG. 6C may include doping the channel layer 455 with the dopant 490 (e.g., boron or another suitable p-type dopant). In some embodiments, the channel layer 455 may be doped using ion implantation.

As shown in FIG. 6D, the process 600 may include forming a dielectric layer 610 over or on the channel layer 455. The dielectric layer 610 may comprise, consist of, or consist essentially of silicon dioxide or another suitable dielectric material, among other examples. In some embodiments, the dielectric layer 610 includes an amorphous structure 615 (e.g., lacks a regular crystalline arrangement, resulting in a disordered atomic structure).

As shown in FIG. 6E, the process 600 may include forming the hardened liner 460 from the dielectric layer 610. Forming the hardened liner 460 may include annealing the dielectric layer 610 to transform the amorphous structure 615 to the crystalline structure 475. In some embodiments, annealing the dielectric layer 610 includes using a rapid thermal processing (RTP) technique, which involves quickly heating the dielectric layer 610 and then rapidly cooling the dielectric layer 610 to transform the amorphous structure 615 to the crystalline structure 475.

As shown in FIG. 6F, the process 600 may include forming (e.g., depositing or growing) the dielectric layer 465 over or on the hardened liner 460. The dielectric layer 465 (e.g., a fill structure) may comprise, consist of, or consist essentially of silicon dioxide or another suitable dielectric material, among other examples.

As shown in FIG. 6G, the process 600 may include removing (e.g., etching) portions of the channel layer 455, the hardened liner 460, or the dielectric layer 465 to form a cavity 620. In other words, the process 600 may include recessing the dielectric layer 465. In some embodiments, and as shown in FIG. 6G, a portion 625 of the channel layer 455 remains along an upper sidewall of the cavity 620. Additionally, or alternatively and in some embodiments, a portion 630 of the hardened liner 460 remains along a lower sidewall of the cavity.

In some embodiments, an etchant is used to form the cavity 620. The etchant may have a first etch rate for the dielectric layer 465, a second etch rate for the hardened liner 460, and a third etch rate for the channel layer 455. The first etch rate may be greater than the second etch rate, and the second etch rate may be less than the third etch rate. In other words, and in comparison to the dielectric layer 465 and the channel layer 455, the hardened liner 460 may have a greater resistance to etching due to the presence of the crystalline structure 475.

The variation in etch rates or resistance to etching may form a tapered, angled, or stair shaped profile along a sidewall of the cavity 620. In other words, the cavity 620 may include a tapered shape, an angled shape, or a stair shape. Furthermore, the portion 625 may have an average thickness T1 and the portion 630 may have an average thickness T2, where T2 is greater than T1.

As shown in FIG. 6H, the process 600 may include forming (e.g., depositing or growing) the plug structure 470 in the cavity 620. The plug structure 470 may comprise, consist of, or consist essentially of silicon (e.g., polycrystalline silicon) or another suitable semiconductive material, among other examples. The plug structure 470 may be formed according to the profile of the cavity (e.g., the plug structure 265 may include a tapered shape, an angled shape, or a stair shape). Accordingly, and in some embodiments, an upper width W1 of the plug structure 470 is greater than a lower width W2 of the plug structure 470.

Additionally, the process 600 in FIG. 6H may include doping the plug structure with the dopant 485 (e.g., phosphorous or another suitable n-type dopant). In some embodiments, the plug structure 470 may be doped using ion implantation.

After formation of the plug structure 470, one or more additional semiconductor processing operations may be performed as part of forming a semiconductor device including the pillar structure 435. The one or more semiconductor processing operations may increase temperature(s) of the plug structure 470, the hardened liner 460, or the channel layer 455. In such cases, a portion of the hardened liner 460 (e.g., the portion 630) may inhibit diffusion of the dopant 485 impurities into the channel layer 455, to maintain and satisfy a voltage threshold of a channel that includes the channel layer 455.

As indicated above, the process steps described in connection with FIGS. 6A-6H are provided as examples. Other examples may differ from what is described with respect to FIGS. 6A-6H. In process steps above that describe forming material, such material may be formed, for example, using chemical vapor deposition, atomic layer deposition, physical vapor deposition, or another deposition technique. In process steps above that describe removing material, such material may be removed, for example, using a wet etching technique (e.g., wet chemical etching), a dry etching technique (e.g., plasma etching), an ion etching technique (e.g., sputtering or reactive ion etching), atomic layer etching, or another etching technique.

In some embodiments, a semiconductor device includes a layer stack including dielectric layers alternating with conductive layers; a pillar structure penetrating into the layer stack, comprising: a semiconductive layer; a dielectric fill; and a dielectric layer that is between the semiconductive layer and the dielectric fill and that includes a crystalline structure; and a plug structure penetrating into the pillar structure, the plug structure having a first portion on the semiconductive layer and having a second portion on the dielectric layer.

In some embodiments, an apparatus includes a channel layer; a liner layer on the channel layer, a dielectric layer on the liner layer; and a digit line contact structure penetrating into the dielectric layer, the digit line contact structure having an upper portion on the channel layer and a lower portion of the digit line contact structure that is separated from the channel layer by the liner layer.

In some embodiments, a method includes forming a stack of dielectric layers alternating with conductive layers; forming a cavity in the stack; forming a semiconductive layer along a contour of the cavity, forming a dielectric layer over the semiconductive layer; annealing the dielectric layer to form a hardened dielectric layer; forming a dielectric fill on the hardened dielectric layer in the cavity; recessing the dielectric fill to form a cavity in the dielectric fill; and forming a plug structure in the cavity.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y-axis and the z-axis, the y-axis is substantially perpendicular to the x-axis and the z-axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, or assembly in use or operation in addition to the orientations depicted in the figures. A structure or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” As used herein, “satisfying a threshold” may, depending on the context, refer to a value being greater than the threshold, greater than or equal to the threshold, less than the threshold, less than or equal to the threshold, equal to the threshold, not equal to the threshold, or the like. All ranges described herein are inclusive of numbers at the ends of those ranges, unless specifically indicated otherwise.

Even though particular combinations of features are recited in the claims or disclosed in the specification, these combinations are not intended to limit the disclosure of implementations described herein. Many of these features may be combined in ways not specifically recited in the claims or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

What is claimed is:

1. A semiconductor device, comprising:
a layer stack including dielectric layers alternating with conductive layers;
a pillar structure penetrating into the layer stack, comprising:
a semiconductive layer;
a dielectric fill; and
a dielectric layer that is between the semiconductive layer and the dielectric fill and that includes a crystalline structure; and
a plug structure penetrating into the pillar structure, the plug structure having a first portion on the semiconductive layer and having a second portion on the dielectric layer.

2. The semiconductor device of claim 1, wherein the crystalline structure comprises:
a quartz lattice structure.

3. The semiconductor device of claim 1, wherein the first portion of the plug structure overlaps at least a portion of the dielectric layer of the layer stack.

4. The semiconductor device of claim 1, wherein the second portion of the plug structure overlaps at least a portion of a conductive layer of the layer stack.

5. The semiconductor device of claim 1, wherein the semiconductive layer comprises a first type of dopant, and wherein the plug structure comprises:
a second, opposite type of dopant.

6. The semiconductor device of claim 1, wherein the plug structure includes a tapered shape.

7. An apparatus, comprising:
a channel layer;
a liner layer on the channel layer,
a dielectric layer on the liner layer; and
a digit line contact structure penetrating into the dielectric layer, the digit line contact structure having an upper portion on the channel layer and a lower portion of the digit line contact structure that is separated from the channel layer by the liner layer.

8. The apparatus of claim 7, wherein the liner layer comprises annealed oxide having an ordered crystalline structure, and
wherein the ordered crystalline structure comprises:
a single crystal lattice structure,
a polycrystalline lattice structure, or
a superlattice structure.

9. The apparatus of claim 7, wherein the liner layer comprises an annealed dielectric material, and
wherein the annealed dielectric material comprises:
a spinel structure.

10. The apparatus of claim 7, wherein the channel layer comprises polysilicon doped with boron, and
wherein the digit line contact structure comprises:
polysilicon doped with phosphorous.

11. The apparatus of claim 8, wherein an upper width of the digit line contact structure is greater than a lower width of the digit line contact structure.

12. The apparatus of claim 8, further comprising:
an inter-gate dielectric layer adjacent to the upper portion of the digit line contact structure, and
a word line layer below the inter-gate dielectric layer and adjacent to the lower portion of the digit line contact structure,
wherein a first average thickness of the channel layer between the upper portion of the digit line contact structure and the inter-gate dielectric layer is less than a second average thickness of the channel layer between the lower portion of the digit line contact structure and the word line layer.

13. A method, comprising:
forming a stack of dielectric layers alternating with conductive layers;
forming a cavity in the stack;
forming a semiconductive layer along a contour of the cavity,
forming a dielectric layer over the semiconductive layer;
annealing the dielectric layer to form a hardened dielectric layer;
forming a dielectric fill on the hardened dielectric layer in the cavity;
recessing the dielectric fill to form a cavity in the dielectric fill; and
forming a plug structure in the cavity.

14. The method of claim 13, wherein forming the dielectric layer includes:
depositing a layer of a dielectric material having an amorphous structure.

15. The method of claim 14, wherein annealing the dielectric layer to form the hardened dielectric layer includes:
transforming at least a portion of the dielectric material having the amorphous structure to include a crystalline structure.

16. The method of claim 13, wherein annealing the dielectric layer includes:
using a rapid thermal processing operation.

17. The method of claim 13, wherein recessing the dielectric fill includes:
using an etch operation to recess the dielectric fill,
wherein the etch operation uses an etchant having a first etch rate for the dielectric fill, a second etch rate for the hardened dielectric layer, and a third etch rate for the semiconductive layer,
wherein the first etch rate is greater than the second etch rate, and
wherein the second etch rate is less than the third etch rate.

18. The method of claim 17, wherein using the etch operation includes:
leaving a portion of the semiconductive layer along an upper sidewall of the cavity, and
leaving a portion of the hardened dielectric layer along a lower sidewall of the cavity,
wherein an average thickness of the portion of the hardened dielectric layer is greater than an average thickness of the portion of the semiconductive layer.

19. The method of claim 13, wherein forming the plug structure in the cavity includes:
using an implant operation to form impurities in the plug structure.

20. The method of claim 19, further including:
performing a semiconductor processing operation that increases a temperature of the plug structure, the hardened dielectric layer, and the semiconductive layer,
wherein a portion of the hardened dielectric layer inhibits diffusion of the impurities into the semiconductive layer caused by the temperature to maintain and satisfy a voltage threshold of a channel that includes the semiconductive layer.
